(19) United States
(12) Patent Application Publication
(10) Pub. No.: US 2012/0293939 A1
(43) Pub. Date: Nov. 22, 2012

(54) SLIDABLE SUPPORT STAND

(75) Inventors: Chun-Che Wu, Taipei (TW); Chun-Nan Su, Taipei (TW)

(73) Assignee: PRIMAX ELECTRONICS LTD., Taipei (TW)

(21) Appl. No.: 13/193,094

(22) Filed: Jul. 28, 2011

(30) Foreign Application Priority Data
May 20, 2011 (TW) 100117705

(51) Int. Cl. G06F 1/16; H05K 7/00

(52) U.S. Cl. 361/679.08; 248/371; 248/397

(57) ABSTRACT

The present invention discloses a slidable support stand including a base, a cover and a support piece. The cover is disposed to the base and includes a first cover body and a second cover body. The first cover body is capable of rotating about the base, and the second cover body is pivoted to the first cover body and is capable of rotating about the first cover body. The support piece is disposed to one side of the base and is capable of sliding relative to the base. When the support piece slides out of the side of the base and the second cover body flips to the side of the base, the second cover body leans against the support piece, and thus the first cover body can be used for supporting a tablet computer or a handheld communication device.

### FIELD OF THE INVENTION

The present invention generally relates to a slidable support stand, and more particularly to a slidable support stand capable of supporting a tablet personal computer (tablet PC) or a handheld communication device.

### BACKGROUND OF THE INVENTION

In recent years, the tablet PC is much more popular due to being designed with light and slim shape. The tablet PC is usually equipped with a touch screen, and thus users may key commands to the tablet PC by touching the touch screen, so as to operate the tablet PC. When users operate the tablet PC and desires to key letters or symbols, the touch screen of the tablet PC may pop-up a virtual keyboard image to simulate an actual keyboard device. Therefore, users may key corresponding letters or symbols to the tablet PC by touching each of the images on the virtual keyboard image, so as to directly key letters or symbols without connecting any actual keyboard device.

Since the area of the touch screen of the tablet PC is often smaller than that of the common actual keyboard device, the key images of the virtual keyboard image popped-up on the tablet PC are usually smaller than the keys of the common actual keyboard device, and thus it is likely to touch wrong virtual keys when users try to touch the desired virtual keys. In addition, users used to use the desk PC or the notebook are not adapted to key letters or symbols by touching the virtual keyboard image. Therefore, many users use an additional external keyboard device to connect with the tablet PC, and put the tablet PC on a supporter, such as a bookshelf, for supporting the tablet PC. In another word, the tablet PC is used as a computer host with a screen, and then the external keyboard device is used for keying letters or symbols.

In response to the demand for connecting the tablet PC with the external keyboard, there is a conventional tablet PC supporter with a keyboard having functions of providing a fixed keyboard and supporting the tablet PC as illustrated in FIG. 1. The conventional tablet PC supporter 1 comprises a base 10, a cover 11 and a keyboard 12. A bracket 101 is disposed within the base 10, may be pulled outward from the inside of the base 10, and has a plurality of stop portions 102. The cover 11 has a flipping portion 111 capable of being flipped backward to lean against the stop portions 102 after the cover 11 is lifting up for exposing the keyboard 12. Therefore, users may put the tablet PC 13 on the base 10 and thus the tablet PC 13 can be supported by the cover 11. Further, the flipping portion may lean against different stop portions 102 according to requirements of users, so as to support the tablet PC with different tilt angles for providing users with better visual effects.

However, the base 10 of the traditional tablet PC supporter described above must reserve a space for the bracket 101 due to the mechanism design of the bracket 101, and thus the thickness of the base 10 must be thicker. Hence, the traditional tablet PC supporter is disadvantageous to be carried. In addition, when users put the tablet PC supporter 1 on a table, whole of the bracket 101 must be pulled out from the base 10 no matter what angle the cover 11 leans against the carrier 11 with, so as to occupy a larger space on the table. Accordingly, it is desired to provide a tablet PC supporter with advantages of having thinner thickness and occupying less space.

### SUMMARY OF THE INVENTION

The present invention is directed to a slidable support stand, which has a keyboard and a wireless transmission device capable of matching up with a tablet PC or a handheld communication device.

The present invention is further directed to a slidable support stand with advantages of having thinner thickness and occupying smaller spaces.

In a preferred embodiment, the present invention provides a slidable support stand capable of supporting a tablet PC or a handheld communication device, wherein the slidable support stand comprises:

a base, disposed with a first slide rail;

a cover, disposed to the base and capable of rotating about the base, wherein the cover comprises a first cover body and a second cover body, the first cover body is disposed to the base and capable of rotating about the base, and the second cover body is pivoted to the first cover body and capable of rotating about the first cover body; and

a support piece, disposed to a side of the base, wherein the support piece comprises a support portion, a first connect portion extending from an end of the support portion and a second connect portion extending from another end of the support portion, the first connect portion is disposed with a first slide piece, the first slide piece is disposed to the first slide rail, when the support portion slides out of the side of the base and the second cover body flips to the side of the base, the second cover body leans against the support portion.

In a preferred embodiment, the support piece and the first slide piece are formed integrally.

In a preferred embodiment, the first slide rail is a rod and passes through the first slide piece, and a first stop portion and a second stop portion are respectively disposed to two ends of the first slide rail and capable of stopping the first slide piece and holding the first slide rail.

In a preferred embodiment, the slidable support stand further comprises a first position limit structure, wherein the first position limit structure is disposed in the base and capable of limiting a position of the first slide piece.

In a preferred embodiment, the first position limit structure further comprises a plurality of position limit pieces, wherein the plurality of position limit pieces are parallel to the first slide rail, each of the plurality of position limit pieces has a protruding portion thereon, and the first slide piece has a first denting portion corresponding to the plurality of protruding portions.

In a preferred embodiment, the slidable support stand further comprises a second slide piece disposed to the first connect portion, wherein the second slide piece is disposed to the first slide rail and has a second denting portion corresponding to the plurality of protruding portions, and thus the first position limit structure is capable of limiting a position of the second slide piece.

In a preferred embodiment, the slidable support stand further comprises a second slide rail and a second position limit structure disposed in the base, and the second connect portion is disposed with a second slide piece and a third slide piece, wherein the second slide piece and the third slide piece are disposed to the second slide rail, and positions thereof are limited by the second position limit structure.

In a preferred embodiment, the first slide rail has a first wing portion and a second wing portion, wherein the first slide piece has a first slide portion and a second slide portion, the first slide portion fits onto the first wing portion, and the second slide portion fits onto the second wing portion.

In a preferred embodiment, the base is further disposed with a second slide rail, the slidable support stand further comprises a second slide piece, and the second slide rail has a third wing portion and a fourth wing portion, wherein the second slide piece is disposed to the second connect portion and has a third slide portion and a fourth slide portion, the third slide portion fits onto the third wing portion, and the fourth slide portion fits onto the fourth wing portion.

In a preferred embodiment, the first connect portion and the second connect portion are respectively perpendicular to the support portion, and the first connect portion, the second connect portion and the support portion are formed integrally.

In a preferred embodiment, the slidable support stand further comprises a keyboard and a wireless transmission device, wherein the keyboard and the wireless transmission device are disposed to the base, and the wireless transmission device is capable of transmitting a signal with the keyboard and the tablet PC or the handheld communication device supported by the slidable support stand.

In a preferred embodiment, the wireless transmission device is a bluetooth transmission device.

In a preferred embodiment, the slidable support stand further comprises a circuit board disposed in the base and a power switch disposed on the circuit board, and the first slide piece is further disposed with an extending portion, wherein the power switch is pressed by the extending portion and thus switched off when the support piece is located at an initial position, and the power switch is separated from the extending portion and thus switched on when the support piece leaves the initial position.

In a preferred embodiment, the wireless transmission device is activated and switched into a searching mode when the power switch is switched on for the first time.

In a preferred embodiment, the slidable support stand further comprises a dent disposed to the base, wherein the dent is capable of containing the tablet PC or the handheld communication device.

### BRIEF DESCRIPTION OF THE DRAWINGS

FIG. 1 illustrates a schematic view of a conventional tablet PC supporter.

FIG. 2 illustrates an external schematic view of a slidable support stand being completely folded according to a first preferred embodiment of the present invention.

FIG. 3 illustrates a schematic view of the slidable support stand as illustrated in FIG. 2 being flipped out.

FIG. 4 illustrates an internal partial top view of a base of a slidable support stand according to the first preferred embodiment of the present invention.

FIG. 5 illustrates an internal partial top view of a base of a slidable support stand according to the first preferred embodiment of the present invention, wherein the support portion is separated from a side of the base.

FIG. 6A and FIG. 6B respectively illustrates an internal partial top view of a base of a slidable support stand according to a second preferred embodiment of the present invention, wherein FIG. 6A illustrates the support portion is not separated from a side of the base yet, while FIG. 6B illustrates the support portion has been separated from the side of the base.

FIG. 7 illustrates an internal partial top view of a base of a slidable support stand according to a third preferred embodiment of the present invention.

FIG. 8 illustrates an internal partial top view of a base of a slidable support stand according to a fourth preferred embodiment of the present invention.

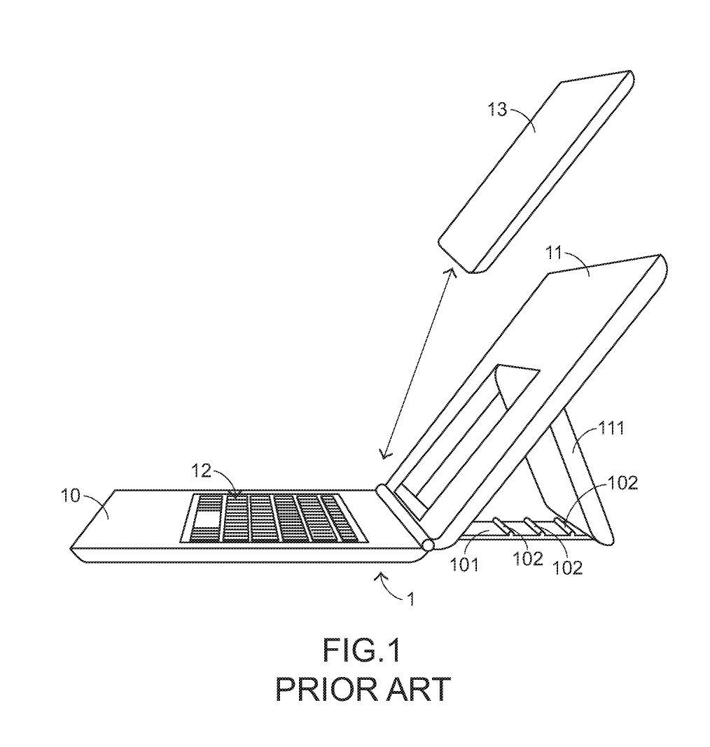

### DETAILED DESCRIPTION OF THE PREFERRED EMBODIMENT

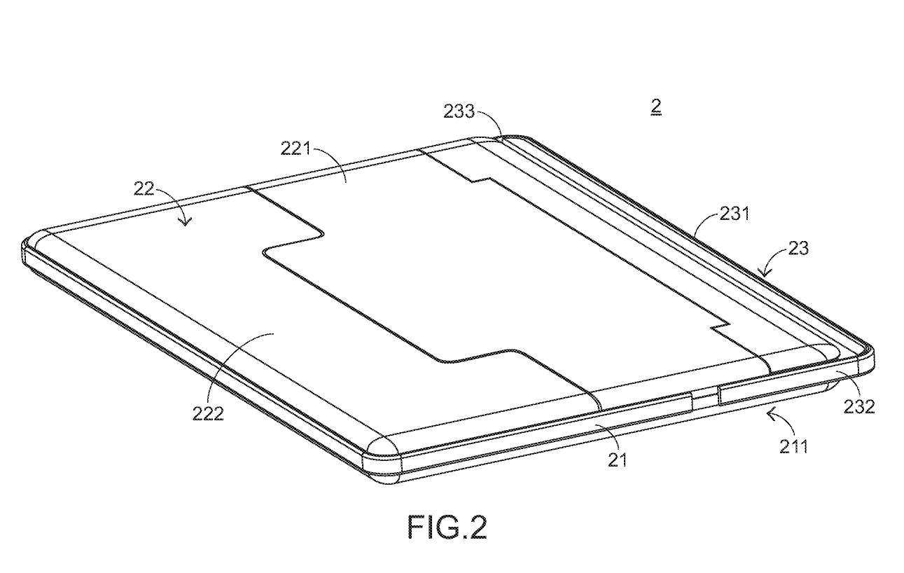

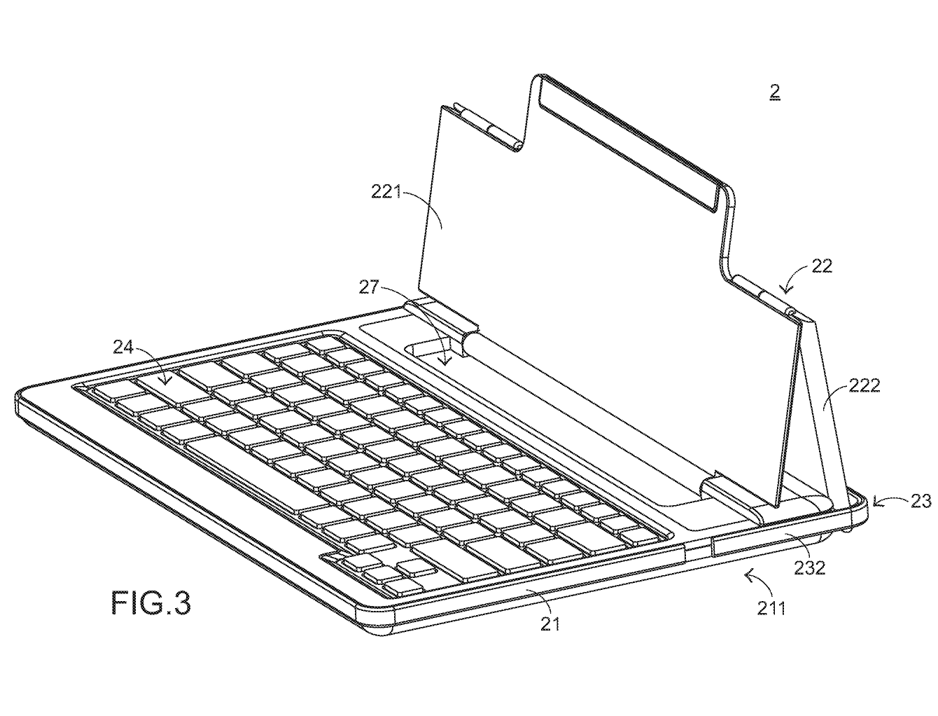

The slidable support stand of the present invention is capable of supporting a tablet PC or a handheld communication device. FIG. 2 illustrates an external schematic view of a slidable support stand being completely folded according to a first preferred embodiment of the present invention. FIG. 3 illustrates a schematic view of the slidable support stand as illustrated in FIG. 2 being flipped out. Referring to FIG. 2 and FIG. 3 together, the slidable support stand 2 comprises a base 21, a cover 22, a support piece 23, a keyboard 24 and a dent 27. The cover 22 is disposed to the base 21, and the cover 22 comprises a first cover body 221 and a second cover body 222, wherein the first cover body 221 is disposed to the base 21 and capable of rotating about the base 21, and the second cover body 222 is pivoted to the first cover body 221 and capable of rotating about the first cover body 221. Both of the keyboard 24 and the dent 27 are disposed to the upper surface of the base 21. The support piece 23 is disposed to a side 211 of the base 21 and capable of sliding relative to the base 21. The support piece 23 comprises a support portion 231, a first connect portion 232 extending from an end of the support portion 231 and a second connect portion 233 extending from another end of the support portion 231. In a preferred embodiment, the first connect portion 232 and the second connect portion 233 are perpendicular to the support portion 231 respectively, and the first connect portion 232, the second connect portion 233 and the support portion 231 are formed integrally. Herein, when the support portion 231 slides out of the side 211 of the base 21 and the second cover body 222 flips to the side 211 of the base 21, the second cover body 222 is capable of leaning against the support portion 231, and the cover body 221 is capable of being used for carrying a tablet PC or a handheld communication device.

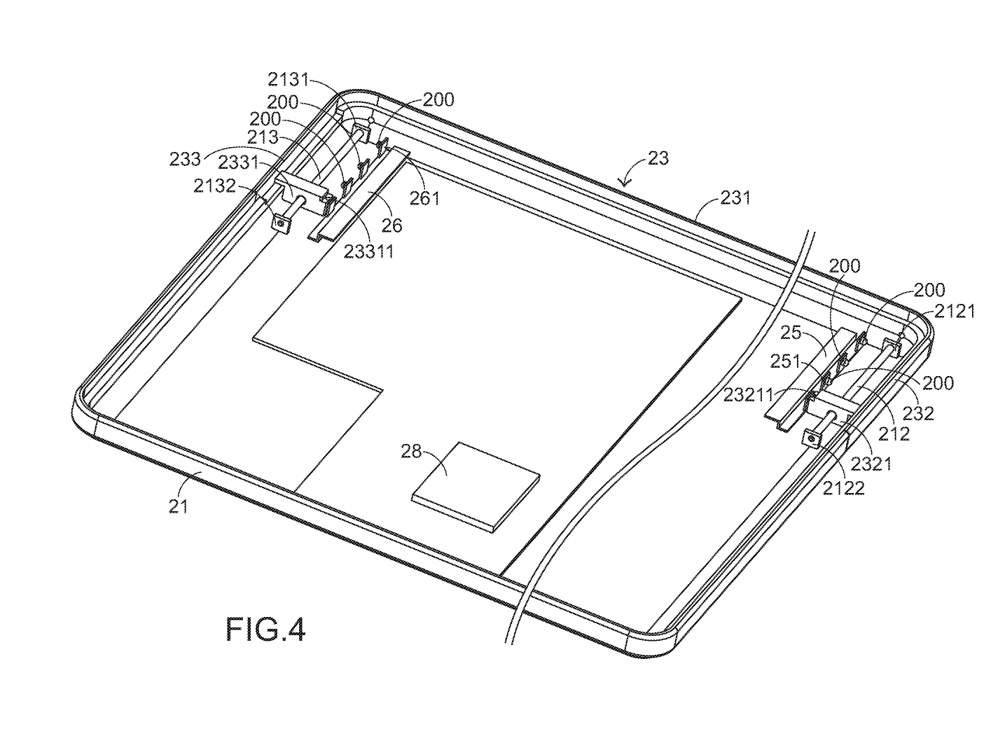

The detailed structure of the slidable support stand 2 of the present invention is illustrated herein after. FIG. 4 illustrates an internal partial top view of a base 21 of a slidable support stand according to the first preferred embodiment of the present invention. Referring to FIG. 4, a wireless transmission device 28 is disposed in the base 21, wherein the wireless transmission device 28 is capable of transmitting a signal with the keyboard 24 and the tablet PC or the handheld communication device (not shown) supported by the slidable support stand 2. In a preferred embodiment, the wireless transmission device 28 is a bluetooth transmission device.

Furthermore, the base 21 is disposed with a first slide rail 212 and a second slide rail 213, wherein each of the first slide rail 212 and the second slide rail 213 is a rod. In addition, the first connect portion 232 of the support piece 23 is disposed with a first slide piece 2321, and the second connect portion 233 of the support piece 23 is disposed with a second slide piece 2331. In the present preferred embodiment, the support piece 23, the first slide piece 2321 and the second slide piece 2331 are formed integrally. However, in other embodiment, the first slide piece 2321 and the second slide piece 2331 can further be two independent components connecting with the support piece 23. The first slide rail 212 passes through the first slide piece 2321, and two ends thereof are disposed with a first stop portion 2121 and a second stop portion 2122 respectively, while the second slide rail 213 passes through the second slide piece 2331, and two ends thereof are disposed with a third stop portion 2131 and a fourth stop portion 2132 respectively. Herein, the first stop portion 2121 and the second stop portion 2122 are capable of stopping the first slide piece 2321 and holding the first slide rail 212, and the third stop portion 2131 and the fourth stop portion 2132 are capable of stopping the second slide piece 2331 and holding the second slide rail 213.

The slidable support stand 1 further comprises a first position limit structure 25 and a second position limit structure 26, and both of the first position limit structure 25 and the second position limit structure 26 are disposed within the base 21. In addition, the first position limit structure 25 comprises a plurality of first position limit pieces 251, and the second position limit structure 26 comprises a plurality of second position limit pieces 261, wherein each of the plurality of first position limit pieces 251 and the plurality of second position limit pieces 261 has a protruding portion 200 thereon. Herein, the plurality of first position limit pieces 251 are parallel to the first slide rail 212, while the plurality of second position limit pieces 261 are parallel to the second slide rail 213. Furthermore, the first slide piece 2321 has a first denting portion 23211 corresponding to the plurality of protruding portions 200 on the plurality of first position limit pieces 251, while the second slide piece 2331 has a second denting portion 23311 corresponding to the plurality of protruding portions 200 on the plurality of second position limit pieces 261.

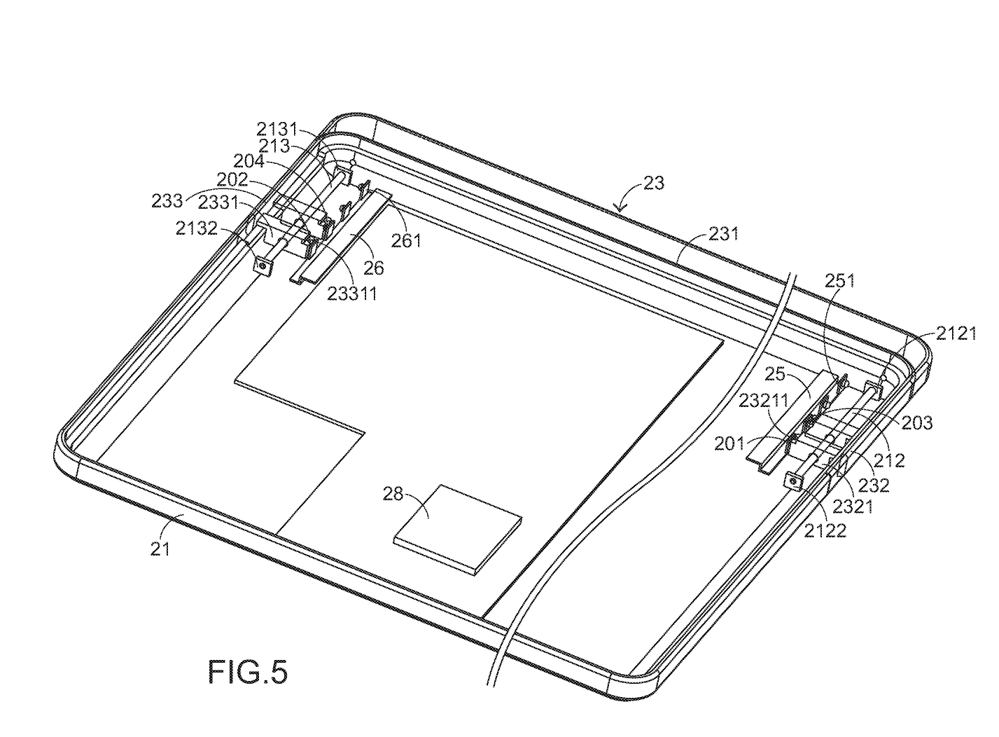

FIG. 5 illustrates an internal partial top view of a base of a slidable support stand according to the first preferred embodiment of the present invention, wherein the support portion is separated from a side of the base. Referring to FIG. 5, as shown in the figure, before users pull the support portion 231 moving outwards to let the support portion 231 separate from the base 21, the first denting portion 23211 of the first slide piece 2321 is fastened with a first protruding portion 201 of the plurality of first limit piece 251, and the second denting portion 23311 of the second slide piece 2331 is fastened with a second protruding portion 202 of the plurality of second limit piece 261. In contrast, when users pull the support portion 231 moving outwards to let the support portion 231 separate from the base 21, the first slide piece 2321 is separated from the first protruding portion 201 and then fastened with a third protruding portion 203, while the second protruding portion 202 is also separated from the second protruding portion 202 and then fastened with a fourth protruding portion 204. In addition, if users do not pull the support portion 231 moving outwards any more at this time, the support piece 23 is fastened at a location as the dashed line illustrated in FIG. 5.

Referring to FIG. 3 and FIG. 5 together, when the support portion 231 is pulled out and fastened at the location as the dashed line illustrated in FIG. 5, users may flip over the cover 22 and then flip the second cover body 222 into a space formed between the support portion 231 drawn as dashed line and the base 21, so as to let the second cover body 222 lean against the support portion 231. After that, users may put a tablet PC or a handheld communication device (not shown) to the dent 27, and then the tablet PC or the handheld communication device may be supported by the first cover body 221. At this time, users may switch on the power switches of the keyboard 24 and the wireless transmission device 28, so as to key letters or symbols to the tablet PC or the handheld communication device by using the keyboard 24. Certainly, users only need to pull the support piece 23 moving outwards again when users desire to adjust the tilt angle of the tablet PC or the handheld communication device.

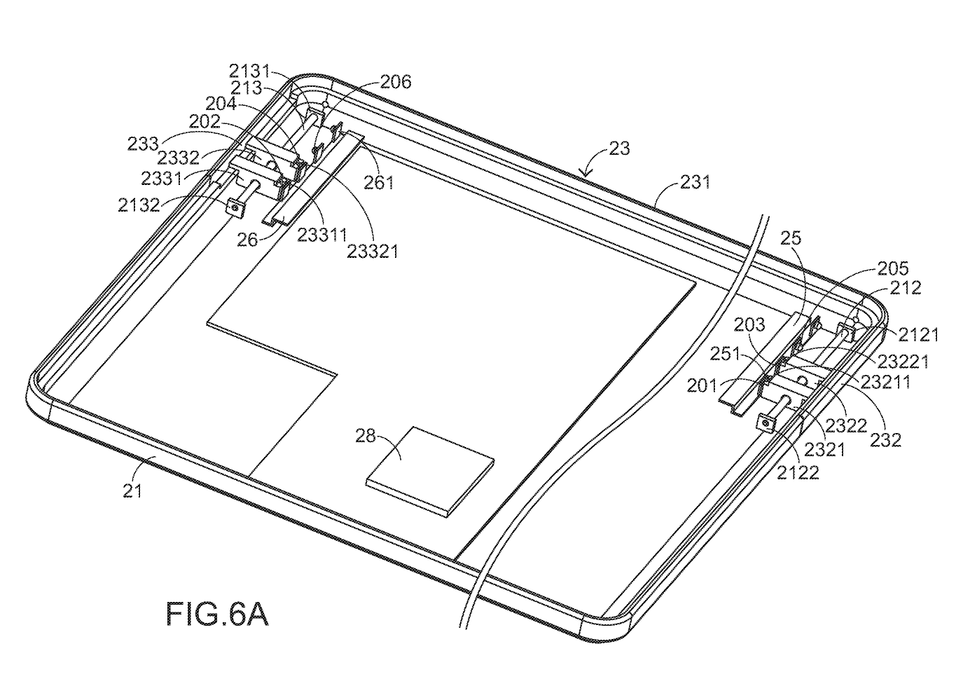

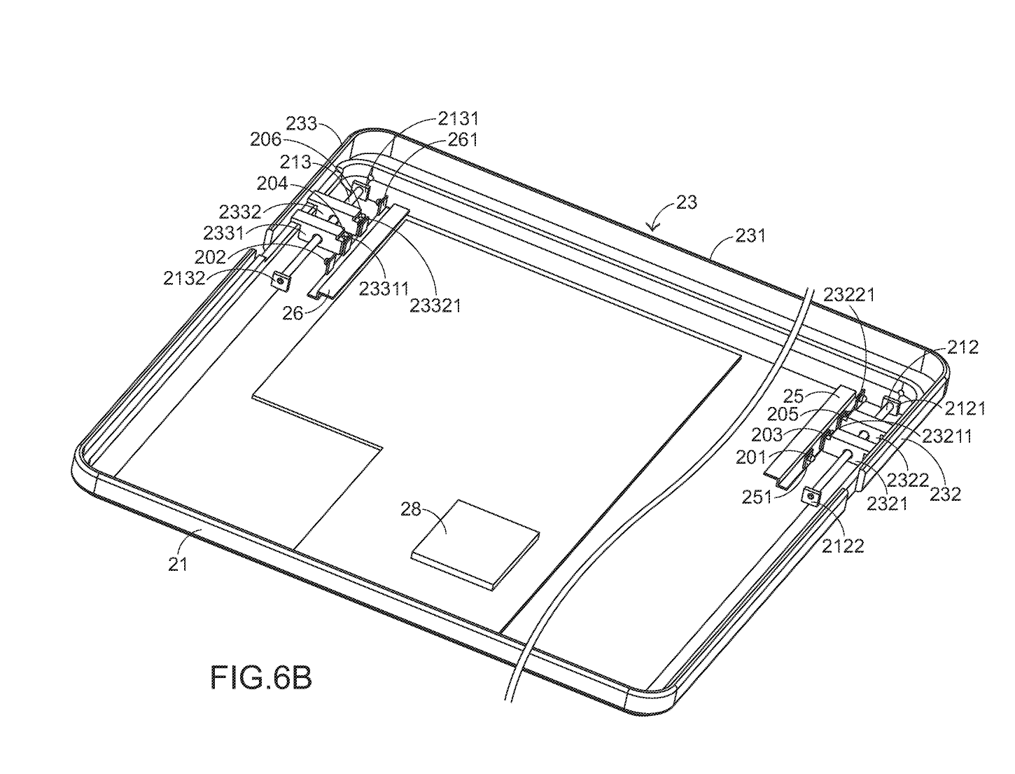

FIG. 6A and FIG. 6B respectively illustrates an internal partial top view of a base of a slidable support stand according to a second preferred embodiment of the present invention, wherein FIG. 6A illustrates the support portion is not separated from a side of the base yet, while FIG. 6B illustrates the support portion has been separated from the side of the base. Referring to FIG. 6A and FIG. 6B, what different from the first preferred embodiment described above are that the first connect portion 232 is further disposed with a third slide piece 2322 and the second connect portion 233 is further disposed with a fourth slide piece 2332. The third slide piece 2322 has a third denting portion 23221 disposed thereon, and the first slide rail 212 passes through the first slide piece 2321 and the third slide piece 2322, while the fourth slide piece 2332 has a fourth denting portion 23321 disposed thereon, and the second slide rail 213 passes through the second slide piece 2331 and the fourth slide piece 2332.

Operation steps of the present embodiment are illustrated herein after. Referring to FIG. 6A first, before users pull the support portion 231 moving outwards, the first slide piece 2321 is fastened with the first protruding portion 201 of the plurality of first limit piece 251, the second slide piece 2331 is fastened with the second protruding portion 202 of the plurality of second limit piece 261, the third slide piece 2322 is fastened with the third protruding portion 203 of the plurality of first limit piece 251, and the fourth slide piece 2332 is fastened with the fourth protruding portion 204 of the plurality of second limit piece 261. In contrast, referring to FIG. 6B, when users pull the support portion 231 moving outwards, the first slide piece 2321, the second slide piece 2331, the third slide piece 2322 and the fourth slide piece 2332 respectively separates from the first protruding portion 201, the second protruding portion 202, the third protruding portion 203 and the fourth protruding portion 204. After that, the first slide piece 2321 and the second slide piece 2331 are respectively further fastened with the third protruding portion 203 and the fourth protruding portion 204, while the third slide piece 2322 and the fourth slide piece 2332 are respectively fastened with a fifth protruding portion 205 and a sixth protruding portion 204. In another word, the connection between the support piece 23 and the base 21 becomes more stable by further adding the third slide piece 2322 and the fourth slide piece 2332.

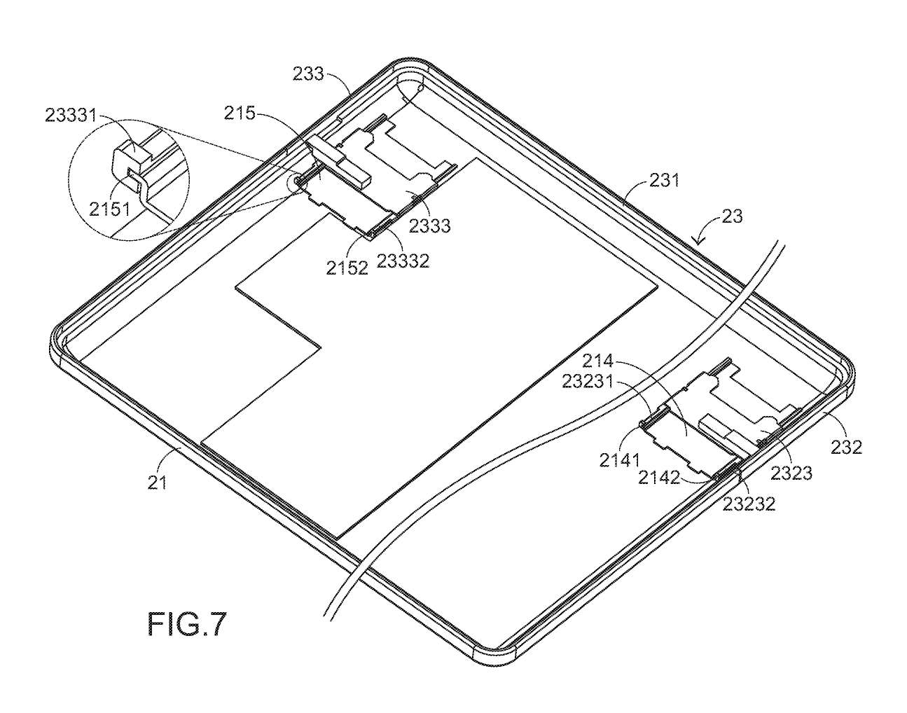

FIG. 7 illustrates an internal partial top view of a base of a slidable support stand according to a third preferred embodiment of the present invention. Referring to FIG. 7, what different from the first and the second embodiments described above is that each of the first slide rail 212 and the second slide rail 213 of the first and the second embodiments described above is a rod, but the slide rail of the present embodiment is a slide rail with two wing portions.

As illustrated in the figure, the base 21 is disposed with a third slide rail 214 and a fourth slide rail 215 therein, wherein the third slide rail 214 has a first wing portion 2141 and a second wing portion 2142, and the fourth slide rail 215 has a third wing portion 2151 and a fourth wing portion 2152. In addition, the first connect portion 232 is disposed with a fifth slide piece 2323, and the second connect portion 233 is disposed with a sixth slide piece 2333, wherein the fifth slide piece 2323 has a first slide portion 23231 and a second slide portion 23232, and the sixth slide piece 2333 has a third slide portion 23331 and a fourth slide portion 23332. Herein, the first slide portion 23231 is fit into the first wing portion 2141, the second slide portion 23232 is fit into the second wing portion 2142, the third slide portion 23331 is fit into the third wing portion 2151, and the fourth slide portion 23332 is fit into the fourth wing portion 2152. Therefore, the fifth slide piece 2323 and the sixth slide piece 2333 are capable of sliding relative to the third slide rail 214 and the fourth slide rail 215 respectively, and thus the support piece 23 is capable of being pulled out from the side 211 of the base 21.

It should be noted that those of skill in the art may recognize other implementation examples with different aspects about the combinations of the slide rail and the slide piece, and thus the implementation examples should not be limited by the first, the second and the third preferred embodiments.

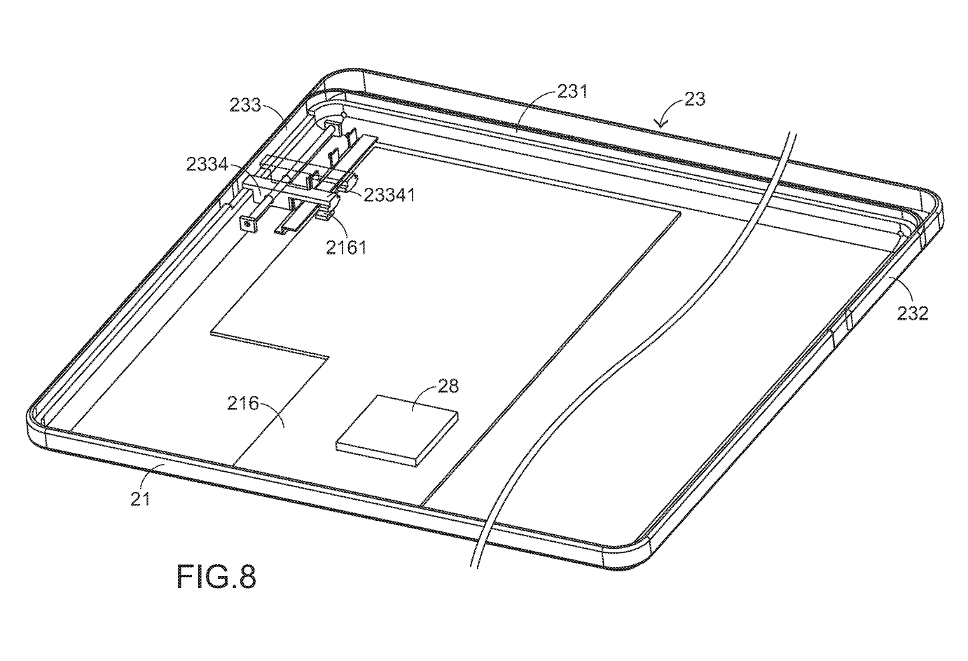

FIG. 8 illustrates an internal partial top view of a base of a slidable support stand according to a fourth preferred embodiment of the present invention. As illustrated in the figure, the base 21 has a circuit board 216 disposed therein, the circuit board 216 has a power switch 2161 disposed thereon, and the wireless transmission device 28 is disposed on the circuit board 216 as well and electrically connects with the power switch 2161. In addition, the second connect portion 233 is disposed with a seventh slide piece 2334, and the second slide rail 213 passes through the seventh slide piece 2334, and thus the seventh slide piece 2334 is capable of sliding relative to the second slide rail 213. Furthermore, the seventh slide piece 2334 is further disposed with an extending portion 23341. Before users pull the support portion 231 moving outwards from the base 21, the support piece 23 is located at an initial position, and the power switch 2161 is switched off due to being pressed by the extending portion 23341. In contrast, after users pull the support portion 231 moving outwards from the base 21 to let the support piece 23 leave the initial position, the extending portion 23341 is separated from the power switch 2161, so as to switch on the power switch 2161. Therefore, the wireless transmission device 28 and the keyboard 12 are able to be operated after the power switch 2161 is switched on. Note that when the power switch 2161 is switched on for the first time, the wireless transmission device 28 is activated and switched into a searching mode. When the wireless transmission device 28 is switched into the searching mode, users must turn on a bluetooth transmission function of the tablet PC or the handheld communication device for searching and connecting with the wireless transmission device 28, and then the tablet PC or the handheld communication device is capable of transmitting a signal with the keyboard 12. After that, users may key letters and commands to the tablet PC or the handheld communication device supported on the slidable support stand of the present invention by using the keyboard 12.

Moreover, when the power switch 2161 is switched on again, the tablet PC or the handheld communication device of users transmits signals with the wireless transmission device 28 automatically, and thus users may key letters and commands to the tablet PC or the handheld communication device supported on the slidable support stand of the present invention by using the keyboard 12 directly. It should be noted that the extending portion 23341 in other preferred embodiments may further be disposed to the seventh slide piece 2334 and contact with the power switch 2161 by other manners and should not be limited by the implementation aspects of the present embodiment.

In summary, the slidable support stand of the present invention utilizes the support piece disposed at a side of the base to achieve miniaturization. Furthermore, users may control the distance that the support piece being pulled out from the base according to different requirements (for example the desired tilt angle of the tablet PC), so as to occupy less space.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A slidable support stand capable of supporting a tablet computer or a handheld communication device, wherein the slidable support stand comprising:
a base, disposed with a first slide rail;
a cover, disposed to the base and capable of rotating about the base, wherein the cover comprises a first cover body and a second cover body, the first cover body is disposed to the base and capable of rotating about the base, and the second cover body is pivoted to the first cover body and capable of rotating about the first cover body; and
a support piece, disposed to a side of the base, wherein the support piece comprises a support portion, a first connect portion extending from an end of the support portion and a second connect portion extending from another end of the support portion, the first connect portion is disposed with a first slide piece, the first slide piece is disposed to the first slide rail, when the support portion slides out of the side of the base and the second cover body flips to the side of the base, the second cover body leans against the support portion.

2. The slidable support stand as claimed in claim 1, wherein the support piece and the first slide piece are formed integrally.

3. The slidable support stand as claimed in claim 1, wherein the first slide rail is a rod and passes through the first slide piece, and a first stop portion and a second stop portion are respectively disposed to two ends of the first slide rail and capable of stopping the first slide piece and holding the first slide rail.

4. The slidable support stand as claimed in claim 1, further comprising a first position limit structure, wherein the first position limit structure is disposed in the base and capable of limiting a position of the first slide piece.

5. The slidable support stand as claimed in claim 4, wherein the first position limit structure comprises a plurality of position limit pieces, the plurality of position limit pieces are parallel to the first slide rail, each of the plurality of position limit pieces has a protruding portion thereon, and the first slide piece has a first denting portion corresponding to the plurality of protruding portions.

6. The slidable support stand as claimed in claim 4, further comprising a second slide piece disposed to the first connect portion, wherein the second slide piece is disposed to the first slide rail and has a second denting portion corresponding to the plurality of protruding portions, and thus the first position limit structure is capable of limiting a position of the second slide piece.

7. The slidable support stand as claimed in claim 4, further comprising a second slide rail and a second position limit structure disposed in the base, and the second connect portion is disposed with a second slide piece and a third slide piece, wherein the second slide piece and the third slide piece are disposed to the second slide rail, and positions thereof are limited by the second position limit structure.

8. The slidable support stand as claimed in claim 1, wherein the first slide rail has a first wing portion and a second wing portion, the first slide piece has a first slide portion and a second slide portion, the first slide portion fits onto the first wing portion, and the second slide portion fits onto the second wing portion.

9. The slidable support stand as claimed in claim 8, wherein the base is further disposed with a second slide rail, the slidable support stand further comprises a second slide piece, the second slide rail has a third wing portion and a fourth wing portion, the second slide piece is disposed to the second connect portion and has a third slide portion and a fourth slide portion, the third slide portion fits onto the third wing portion, and the fourth slide portion fits onto the fourth wing portion.

10. The slidable support stand as claimed in claim 1, wherein the first connect portion and the second connect portion are respectively perpendicular to the support portion, and the first connect portion, the second connect portion and the support portion are formed integrally.

11. The slidable support stand as claimed in claim 1, further comprising a keyboard and a wireless transmission device, wherein the keyboard and the wireless transmission device are disposed to the base, and the wireless transmission device is capable of transmitting a signal with the keyboard and the tablet personal computer or the handheld communication device supported by the slidable support stand.

12. The slidable support stand as claimed in claim 11, wherein the wireless transmission device is a bluetooth transmission device.

13. The slidable support stand as claimed in claim 11, further comprising a circuit board disposed in the base and a power switch disposed on the circuit board, and the first slide piece further disposed with an extending portion, wherein the power switch is pressed by the extending portion and thus switched off when the support piece is located at an initial position, and the power switch is separated from the extending portion and thus switched on when the support piece leaves the initial position.

14. The slidable support stand as claimed in claim 13, wherein the wireless transmission device is activated and switched into a searching mode when the power switch is switched on for the first time.

15. The slidable support stand as claimed in claim 1, further comprising a dent disposed to the base, wherein the dent is capable of containing the tablet personal computer or the handheld communication device.
